(19) United States
(12) Patent Application Publication
(10) Pub. No.: US 2019/0165209 A1
(43) Pub. Date: May 30, 2019

(54) PHOTONIC CRYSTALS IN MICRO LIGHT-EMITTING DIODE DEVICES

(71) Applicant: Facebook Technologies, LLC, Menlo Park, CA (US)

(72) Inventors: James Ronald Bonar, Erskine (GB); Gareth John Valentine, York (GB)

(21) Appl. No.: 16/169,461

(22) Filed: Oct. 24, 2018

Related U.S. Application Data
(60) Provisional application No. 62/592,310, filed on Nov. 29, 2017.

(51) Int. Cl. H01L 33/20; H01L 33/10; H01L 33/46; H01L 33/50; H01L 33/60

(52) U.S. Cl. CPC H01L 33/20; H01L 33/10; H01L 2933/0083; H01L 33/504; H01L 33/60; H01L 33/46

(57) ABSTRACT

Embodiments relate to a micro light emitting diode (LED) having photonic crystal columns extending from a surface to the opposite surface of a transparent semiconductor layer to increase directionality of the light emitted from the micro LED. The photonic crystal columns are arranged in two-dimension. The photonic crystal columns can be produced by etching the transparent semiconductor layer with plasma and growing the photonic crystal columns in the transparent semiconductor layer. The photonic crystal columns can also be produced by etching nano-meter scale regions of the transparent semiconductor layer.

### CROSS-REFERENCE TO RELATED APPLICATION

This application claims the benefit of U.S. Provisional Patent Application No. 62/592,310, filed Nov. 29, 2017, the disclosure of which is hereby incorporated by reference in its entirety.

### BACKGROUND

The present disclosure generally relates to micro light-emitting diodes (micro LEDs), and specifically relates to using photonic crystals to enhance light extraction in micro LEDs applications.

There have been attempts to use micro LEDs in display for their high brightness and energy efficiency. However, most present designs of micro LED devices have low efficiency. Low light extraction efficiency can cause low energy efficiency. Also, low light extraction efficiency can cause significant absorption of light by the substrates of the micro LED devices, resulting in overheating of micro LED devices.

### SUMMARY

Embodiments relate to a micro light emitting diode (LED) having photonic crystal columns that inhibit propagation of emitted light in predetermined directions to reduce divergence of the emitted light. The photonic crystal columns may have a two dimensionally periodic structure and extend through a transparent N-type semiconductor layer of the micro LED. The micro LED also includes a transparent P-type semiconductor layer and a quantum well region between the transparent P-type semiconductor layer and the transparent N-type semiconductor layer. The quantum well region emits light responsive to passing current through the quantum well region. The photonic crystal columns come in contact with the quantum well region and receive light from the quantum well region. The photonic crystal columns function as waveguide for the light and inhibit propagation of the light in predetermined directions to reduce divergence of the light.

In some embodiments, the photonic crystal columns are separated from the quantum well region by a distance that is shorter than a wavelength of the light.

In some embodiments, the photonic crystal columns can be fabricated by etching selective regions of the transparent N-type semiconductor layer to form gaps in the transparent N-type semiconductor layer and growing the photonic crystal columns in these gaps.

In some embodiments, the micro LED can be fabricated by etching nano-meter scale regions of the transparent N-type semiconductor layer to form the photonic crystal columns. There is no etching in the quantum well region.

### BRIEF DESCRIPTION OF THE DRAWINGS

Figure (FIG. 1 is a cross-sectional view of micro LEDs including photonic crystal columns, in accordance with an embodiment.

FIGS. 2A through 2F illustrate a process of fabricating the micro LEDs in FIG. 1, in accordance with an embodiment.

FIGS. 2G through 2H illustrate another process of fabricating the photonic crystal columns of the micro LEDs, in accordance with an embodiment.

FIG. 3 is a cross-sectional diagram illustrating the micro LEDs attached on a semiconductor substrate through an interposer, in accordance with an embodiment.

FIG. 4A is a cross-sectional diagram illustrating propagation of light emitted from micro LEDs without photonic crystal columns, in accordance with an embodiment.

FIG. 4B is a cross-sectional diagram illustrating propagation of light emitted from micro LEDs including photonic crystal columns, in accordance with an embodiment.

FIG. 5 is a diagram illustrating light extraction enhancement by the photonic crystal columns, in accordance with an embodiment.

The figures depict embodiments of the present disclosure for purposes of illustration only.

### DETAILED DESCRIPTION

Embodiments relate to a micro light emitting diode (LED) having photonic crystal columns extending from a surface to the opposite surface of a transparent semiconductor layer to increase directionality of the light emitted from the micro LED. The photonic crystal columns may be are arranged as a two-dimension array. The photonic crystal columns can be produced by etching the transparent semiconductor layer with plasma and growing the photonic crystal columns in the transparent semiconductor layer. Alternatively, the photonic crystal columns can be fabricated by electron-beam lithography (EBL).

FIG. 1 is a cross-sectional view of micro LEDs 100 including photonic crystal columns 150, in accordance with an embodiment. The micro LEDs 100 further include an N-type GaN layer 110, a P-type GaN layer 120, a group of P electrodes 130 on a surface of the P-type GaN layer 120, and a quantum well region 140 on the other surface of the P-type GaN layer 120. Each P electrodes 130 corresponds to one micro LED. Other embodiments of the micro LEDs 100 may include different, additional, or fewer components. For example, the micro LEDs 100 can include an N-type semiconductor that is not N-GaN. Similarly, the micro LEDs 100 can include a P-type semiconductor that is not P-GaN.

Each of the micro LEDs 100 emits light 160 when a potential difference is applied through its corresponding P electrode 130 and N electrode (not shown). The micro LEDs 100 can be used in general lighting devices (e.g., lamps, traffic signals, etc.), data communication systems, self-emitting displays of electronic devices (e.g., television, electronic signs, etc.), and other types of systems. Examples of the electronic device include smart watches, smart phones, wrist band, head-up display etc.

As well known in the art, the micro LEDs 100 include N-type GaN layer 110, P-type GaN layer 120 and a quantum well region 140 comprising one or more quantum wells at the junction of N-type GaN layer 110 and the P-type GaN layer 120. Through the P electrodes 130 and one or more N electrodes (not shown), each micro LED may be supplied with current to activate the micro LED. In some embodiments, the N-type GaN layer 110 is undoped. The N-type GaN layer 110 can be N-GaN semiconductor that comprises an extra layer of undoped GaN.

The interface of the N-type GaN layer 110 and the P-type GaN layer 120 forms a P-N injunction. The quantum well region 140 is a thin layer of semiconductor medium between the N-type GaN layer 110 and the P-type GaN layer 120 wherein recombination of electrons and holes is confined. The light 160 is produced by spontaneous emission, where electrons spontaneously recombine with holes to emit photons. Because free electrons are in the conduction band while holes are in the valence energy band, the energy level of the holes is less than that of the electrons. Consequently, extra energy is dissipated during the process of recombination. The dissipated energy is emitted in the form of photons (light). In the embodiment of FIG. 1, both the N-type GaN layer 110 and the P-type GaN layer 120 are transparent to light. Thus, the light 160 can pass through the N-type GaN layer 110 and the P-type GaN layer 120 and exit from the micro LEDs 100.

The photonic crystal columns 150 reduce divergence of the light 160 and trap the light 160 in y direction. In some embodiments, the photonic crystal columns 150 inhibit propagation of the light 160 in predetermined directions to reduce divergence of the light 160. Photonic crystals can have two and three dimensionally periodic structures with high refractive index contrast. Photonic crystals composed of a periodic sequence of materials with high refractive index contrast are capable of manipulating the interaction between photon and materials and thus controlling propagation direction of light. For example, photonic crystals columns having a periodic optical nanostructure affects the motion of photons.

In the embodiment of FIG. 1, the photonic crystal columns 150 have a two-dimensional structure. That is, the photonic crystal columns 150 are periodic in x and z directions and homogeneous in y direction. As shown in FIG. 1, the photonic crystal columns 150 extend from one surface of the N-type GaN layer 110 to the other surface of the N-type GaN layer 110. Such a two-dimensional photonic crystal pattern is designed for enhancement of light extraction in y direction. In some embodiments, the photonic crystal columns 150 are a square lattice of dielectric columns. In some other embodiments, the photonic crystal columns 150 have a trigonal lattice structure with cylindrical air columns. The period of the crystal can be approximately 420 nm and the cylinder diameter can be about 330 nm. In the embodiment of FIG. 1, the photonic crystal columns 150 are separated from the quantum well region 140 by a distance that is shorter than a wavelength of the light 160.

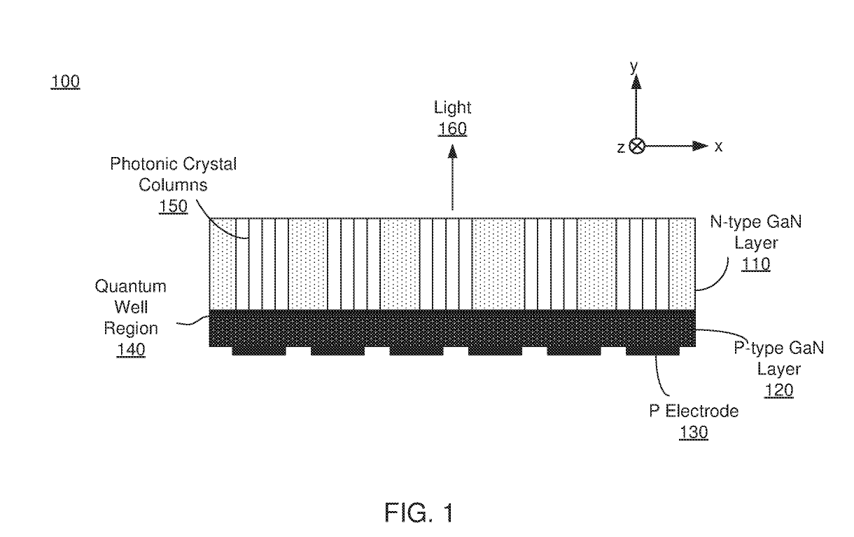

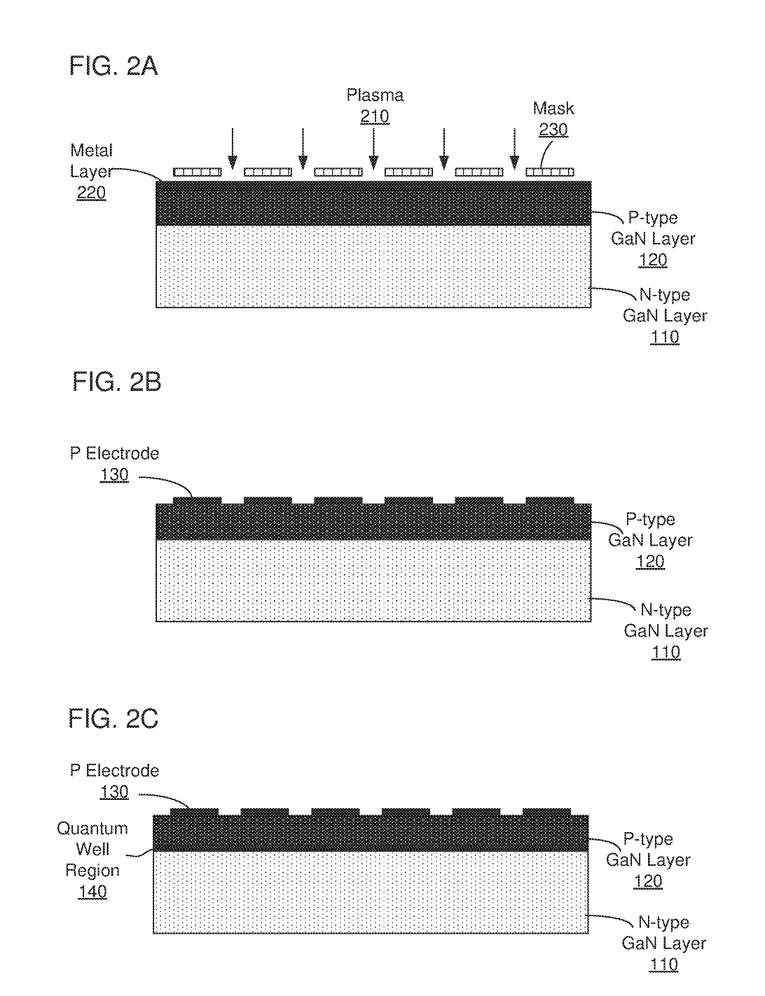

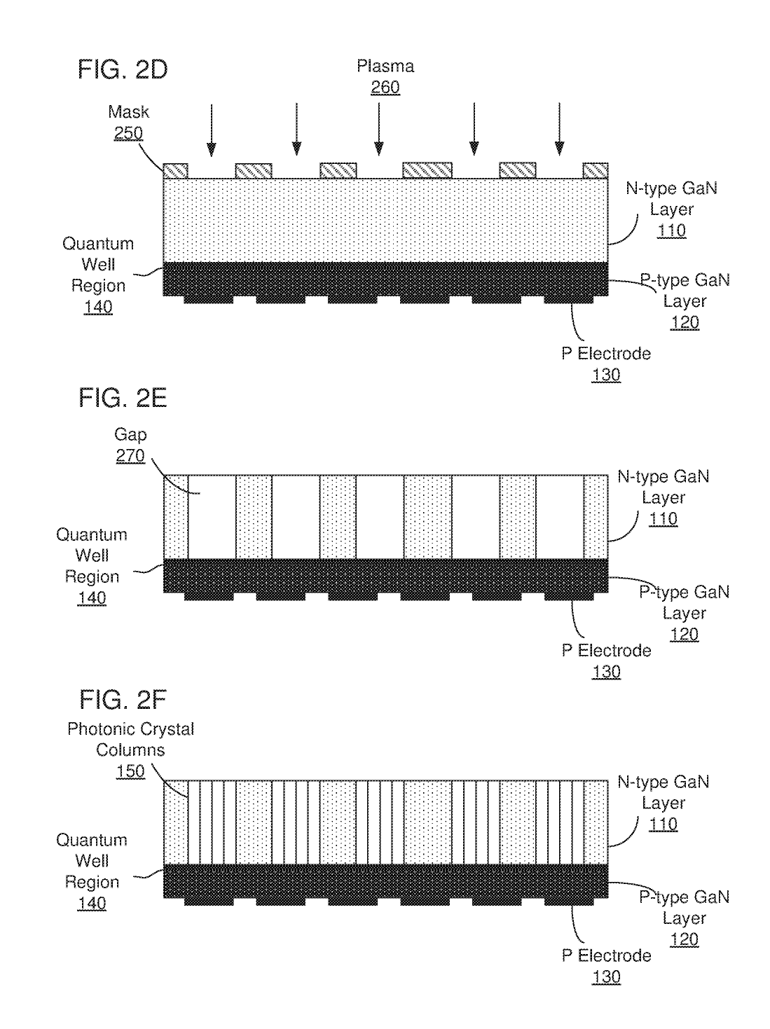

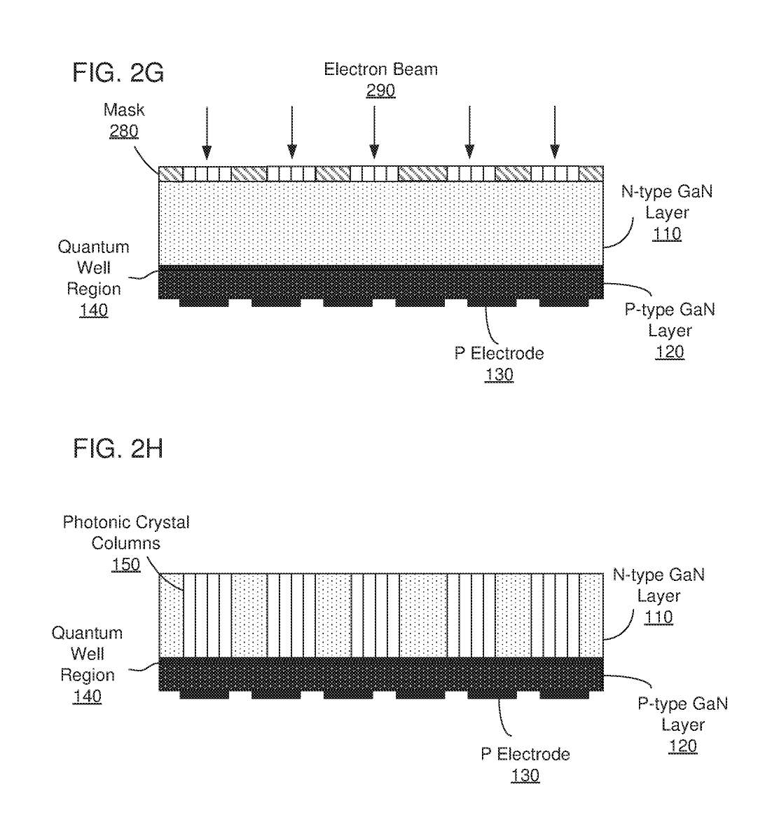

FIGS. 2A through 2F illustrate a process of fabricating the micro LEDs 100 in FIG. 1, in accordance with an embodiment. In other embodiments, the micro LEDs 100 can be produced in different processes than the process shown in FIGS. 2A through 2F. Also, each of the FIGS. 2A through 2F does not necessarily represent one step of the process. That is, each of the FIGS. 2A-F may represent more than one step; or one step may be represented by more than one figure. Likewise, the sequence of FIGS. 2A-F does not represent sequence of the steps in the process. The micro LEDs 100 can be produced through steps in a different sequence from the sequence of FIGS. 2A-F.

FIG. 2A illustrates a plasma etching process to produce the electrodes 130 of the P-type GaN layer 120, in accordance with an embodiment. The electrodes 130 are produced by using plasma 210 to etch a metal layer 220 on the P-type GaN layer 120. As shown in FIG. 2A, the P-type GaN layer 120 is on top of the N-type GaN layer 110. One surface of the P-type GaN layer 120 is covered with the metal layer 220. The metal layer 220 can be deposited onto the surface of the P-type GaN layer 120 in a vacuum metal deposition chamber by, e.g., sputtering or evaporation.

A mask 230 is placed on the metal layer 220 and then selective portions of the metal layer 220 not covered by the mask 230 is exposed to the plasma 210. The mask 230 protects some regions of the metal layer 230 from being etched by the plasma 210. In some embodiments, a photoresist film instead of the mask 230 may be used to cover selective regions of the metal layer 230 to perform photolithographic etching of the metal layer 230. After the plasma etching process or the photolithographic etching is performed, the mask 220 or the photoresist film can be removed.

FIG. 2B shows the electrodes 130 produced by the dry or wet etching process. As a result of the etching, there are gaps between the electrodes 130, corresponding to the gaps within the mask 230 forming non-continuous electrodes 130 on the top of the P-type GaN layer 120. One advantage of the non-continuous electrodes 130, among others, is the individual control of each micro LED emitter. Even though not shown in FIG. 2B, there are electrodes attached on the N-type GaN layer 110 for connecting the N-type GaN layer 110 to the power supplier or the electrical circuit.

FIG. 2C shows the quantum well region 140 fabricated on the P-type GaN layer 120, in accordance with an embodiment. The quantum well region 140 is fabricated when sandwiching a thin layer of material (e.g., InGaN) between the N-type GaN layer 110 and P-type GaN layer 120 causes the energy bands of the composite material to form an energy minimum in the conduction and/or valence band of the thin sandwiched layer. Consequently, the electrons and/or holes in the quantum well region 140 are confined in such a manner that they behave quantum mechanically as particles in a box with discrete, bound energy states. In some embodiments, a channeling technique is used to define one or more active regions of the quantum well region 140.

In some embodiments, the quantum well region 140 includes one or more quantum well structures that comprise a confined active region and one or more non-active regions. The confined active regions emit light responsive to an application of an electrical current to the confined active regions. The non-active regions do not emit light as the current is channeled into the confined active regions.

FIGS. 2D through 2F illustrates a process of fabricating the photonic crystal columns 150 in the N-type GaN layer 110, in accordance with an embodiment. In FIG. 2D, the P-type GaN layer 120 and N-type GaN layer 110 are flipped over so that N-type GaN layer 110 is on top of the P-type GaN layer 120. A mask 250 with holes is placed on top of the N-type GaN layer 110. The N-type GaN layer 110 is selectively exposed to plasma 260 through the holes in the mask 250 and reach the N-type GaN layer 110. The plasma 260 removes regions of N-type GaN layer 110 that are not covered by the mask 250. The density and flow of plasma 260 may be controlled so that the quantum well region 140 is not damaged during the etching process. In some embodiments, the plasma 260 is chlorine-based plasma for semiconductor etching, e.g., Cl₂/BCl₃ plasma. In some embodiments, the plasma etching process mask is formed by submicron patterning using electron-beam, interferometric, or nano-imprint lithography.

FIG. 2E shows that selective regions of the N-type GaN layer 110 etched through, in accordance with an embodiment. There are gaps 270 within the N-type GaN layer 110. In the embodiment of FIG. 2E, the gaps 270 have rectangular cross-sections. However, in some embodiments, cross-sections of the gaps 270 can have a different shape. In the embodiment of FIG. 2E, there is no etching in the quantum well region 140. The quantum well region 140 is not physically etched.

FIG. 2F shows growth of photonic crystal columns 150 in the gaps 250 of the N-type GaN layer 110, in accordance with an embodiment. In some embodiments, oriented two-dimensional microporous silicon membrane is prepared and attached on the quantum well region 140 in the gaps 250 of the N-type GaN layer 110. The silicon membrane forms a silicon template for growing photonic crystals. The complete structure with silicon template is then placed inside an epitaxial deposition chamber for growth of selected material (GaN or another type of material with a high dielectric constant). After growth, the silicon template can be removed, e.g., by selective chemical etching.

FIGS. 2G through 2H illustrate another process of fabricating the photonic crystal columns 150 of the micro LEDs 100, in accordance with an embodiment. In this process, the photonic crystal columns 150 are fabricated by removing nanometer-scale periodic features from the N-type GaN layer 110. The N-type GaN layer 110 is covered with a mask 280. The mask 280 has nanometer-scale periodic gaps. The unmasked regions of the N-type GaN layer 110 are removed, e.g., by plasma etching or photolithographic etching. That results in a two-dimensional photonic crystal structure with air voids in a background of the N-type GaN layer 110.

In some embodiments, the photonic crystal columns 150 are fabricated with electron beam lithography. The electron beam lithography includes impinging a sensitized mask layer deposited on the N-type GaN layer 110 with an electron beam 290. The electron beam 290 is scanned across the mask layer according to a computer generated pattern. After contact with high-energy electrons in the electron beam 290, the mask may be developed and partially removed by chemical means. Electron beam lithography has an advantage of flexibly and precisely writing any arbitrary pattern but it is a time-consuming and expensive process. In some other embodiments, the photonic crystal columns 150 are fabricated with reactive ion plasma etching.

In some embodiments, the photonic crystal columns 150 have a rectangular lattice with a width of 110 nm and a depth of 380 nm. In some alternative embodiments, the photonic crystal columns 150 have a lattice of different shape. For example, the photonic crystal columns 150 has a triangle lattice, e.g., having a depth to width ratio of greater than 3:1 for efficient light extraction. The photonic crystal columns 150 can also have a trapezoidal lattice.

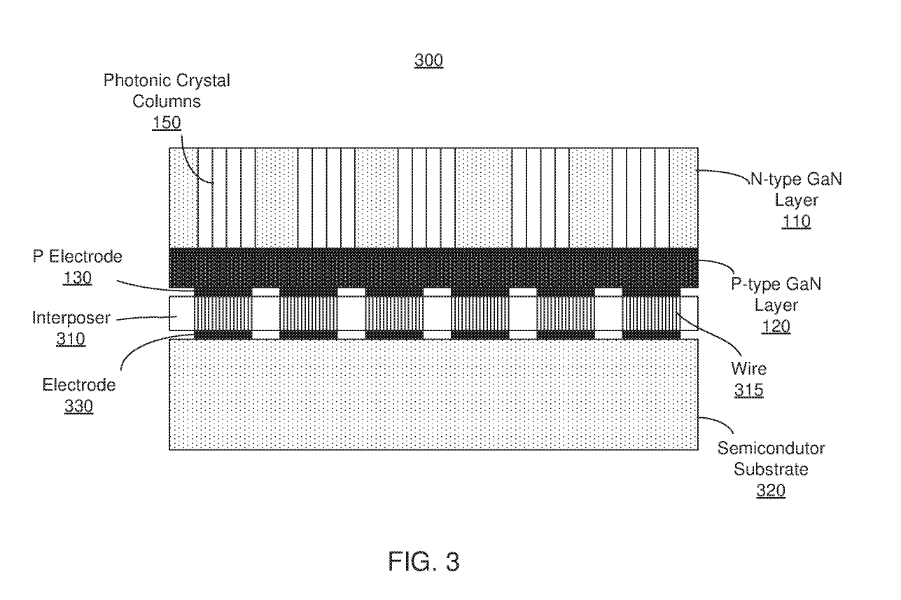

FIG. 3 is a cross-sectional diagram illustrating the micro LEDs 100 attached on a silicon semiconductor substrate 320 through an interposer 310, in accordance with an embodiment. The interposer 310 includes a group of electrically conducting wires 315 connected between the electrodes 130 of the transparent P-type GaN layer 120 and electrodes 330 on an electrical circuit on the silicon semiconductor substrate 320. The interposer 310 provides electrical connection between the P-type GaN layer 120 and the semiconductor substrate 320 under operating temperatures of the micro LEDs 100.

The semiconductor substrate 320 can include an electrical circuit (not shown) to provide electrical current to the N-type GaN layer 110 and P-type GaN layer 120 of the micro LEDs 100 for driving light emission.

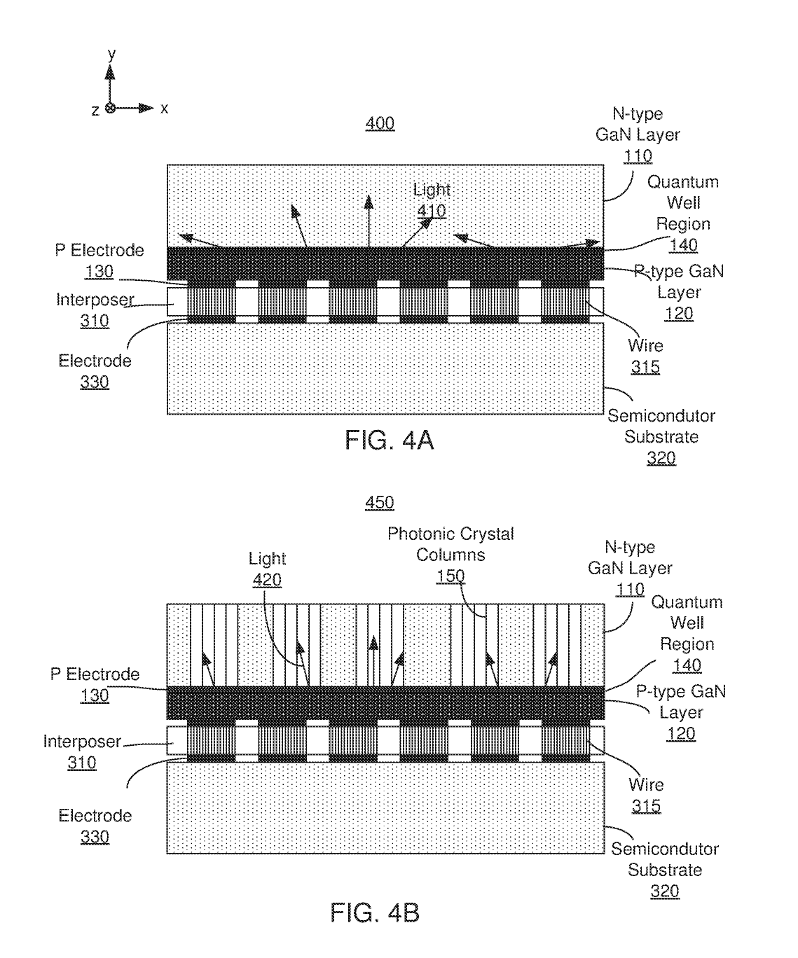

FIG. 4A is a cross-sectional diagram illustrating propagation of light emitted from micro LEDs 400 without photonic crystal columns, in accordance with an embodiment. FIG. 4B is a cross-sectional diagram illustrating propagation of light emitted from micro LEDs 450 including the photonic crystal columns 150, in accordance with an embodiment. Comparison of FIG. 4A and FIG. 4B illustrates light trapping by the photonic crystal columns 150 in y direction.

As shown in FIG. 4A, light 410 emitted from the micro LEDs 400 is not trapped and is emitted in all directions. Even though FIG. 4A shows light propagation in the xy plane, the light 410 can also propagate in the yz and xz planes. Also, in some embodiments, the light 410 can partially be reflected back into the N-type GaN layer 110 or the P-type GaN layer 120, where it may be absorbed and turned into additional heat. This causes energy inefficiency. Sometimes, it can also cause overheating or thermal failure of the micro LEDs 400.

In contrast, FIG. 4B shows that the light 420 emitted from the micro LEDs 450 is controlled by the photonic crystal columns 150. The photonic crystal columns 150 are two-dimensional photonic crystals and functions as waveguide for photons emitted from the quantum well region 140. The photonic crystal columns 150 confines the propagation direction of the light 420 in the y direction. Consequently, the micro LEDs 450 has higher light extraction efficiency. Accordingly, this design has higher energy efficiency and can reduce heating of the micro LEDs 450.

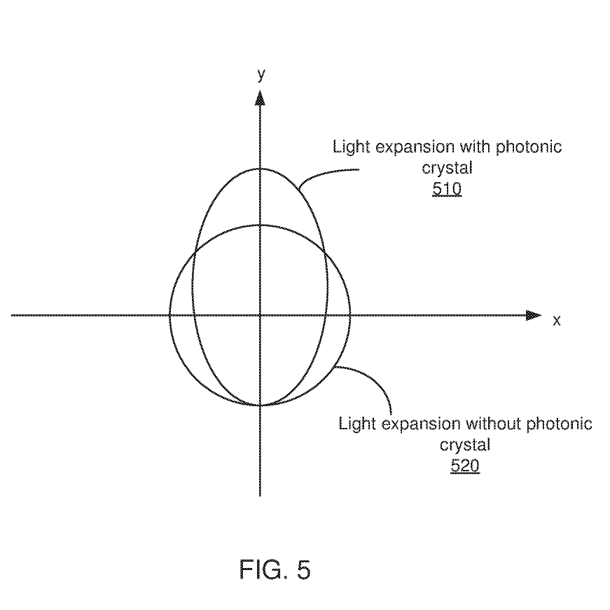

FIG. 5 is a diagram illustrating light extraction enhancement by the photonic crystal columns 150, in accordance with an embodiment. FIG. 5 shows light expansion in the xy plane. Light expansion without photonic crystal columns 150 is a circle, illustrating that light is almost evenly distributed in the xy plane. In contrast, light expansion with photonic crystals 510 is an ellipse having a longer axis in y direction, indicating that more light travels out from the micro LEDs 100 in y direction.

The language used in the specification has been principally selected for readability and instructional purposes, and it may not have been selected to delineate or circumscribe the inventive subject matter. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed is:

1. A light emitting diode comprising:
a transparent P-type semiconductor layer;
a quantum well region on the transparent P-type semiconductor layer and configured to emit light responsive to passing current through the quantum well region;
a transparent N-type semiconductor layer having a first surface abutting the quantum well region and a second surface facing away from the quantum well region; and
a plurality of photonic crystal columns extending from the first surface to the second surface to receive light from the quantum well region.

2. The light emitting diode of claim 1, where the quantum well region is not physically etched.

3. The light emitting diode of claim 1, where the photonic crystal columns come in contact with the quantum well region and no etching is performed in the quantum well region.

4. The light emitting diode of claim 1, where the photonic crystal columns are separated from the quantum well region by a distance that is shorter than a wavelength of the light.

5. The light emitting diode of claim 1, where the photonic crystal columns are configured to inhibit propagation of the light in predetermined directions to reduce divergence of the light.

6. The light emitting diode of claim 1, further comprising an interposer comprising a plurality of electrically conducting wires connected between electrodes on the transparent P-type semiconductor layer and electrodes of an electrical circuit on a silicon semiconductor substrate.

7. The light emitting diode of claim 1, wherein the photonic crystal columns are produced by etching the transparent N-type semiconductor layer with plasma.

8. The light emitting diode of claim 1, wherein the transparent P-type semiconductor is P-GaN.

9. The light emitting diode of claim 1, wherein the transparent N-type semiconductor is N-GaN semiconductor comprising a layer of undoped GaN.

10. A method for producing a light emitting diode, comprising:
sandwiching a layer of semiconductor material between a P-type semiconductor layer and a transparent N-type semiconductor layer to fabricate a quantum well region that emit light responsive to passing current through the quantum well region;
etching through a plurality of selective regions of the transparent N-type semiconductor layer to form gaps in the transparent N-type semiconductor layer; and
growing a plurality of photonic crystal columns in the gaps in the transparent N-type semiconductor layer, the photonic crystal columns configured to receive light from the quantum well region.

11. The method of claim 10, where the photonic crystal columns come in contact with the quantum well region and no etching is performed in the quantum well region.

12. The method of claim 10, where the photonic crystal columns are separated from the quantum well region by a distance that is shorter than a wavelength of the light.

13. The method of claim 10, where the photonic crystal columns are configured to inhibit propagation of the light in predetermined directions to reduce divergence of the light.

14. The method of claim 10, further comprising:
placing an interposer between electrodes on the transparent P-type semiconductor layer and electrodes of an electrical circuit on a silicon semiconductor substrate.

15. The method of claim 10, wherein etching through the plurality of selective regions is performed by exposing the selective regions to plasma.

16. The method of claim 10, wherein growing a plurality of photonic crystal columns in the gaps in the transparent N-type semiconductor layer comprises:
attaching a two-dimensional microporous silicon membrane on the quantum well region in the gaps of the transparent N-type semiconductor layer;
growing the photonic crystal columns in an epitaxial deposition chamber; and
removing the two-dimensional microporous silicon membrane after growing the photonic crystal columns.

17. A method for producing a light emitting diode, comprising:
sandwiching a layer of semiconductor material between a P-type semiconductor layer and a transparent N-type semiconductor layer to fabricate a quantum well region that emits light responsive to passing current through the quantum well region;
placing a mask on the transparent N-type semiconductor layer, the mask comprising nano-meter scale periodic gaps; and
etching unmasked regions of the transparent N-type semiconductor layer to form a plurality of photonic crystal columns in the transparent N-type semiconductor layer, the photonic crystal columns configured to receive light from the quantum well region.

18. The method of claim 17, where the photonic crystal columns come in contact with the quantum well region and where no etching is performed in the quantum well region.

19. The method of claim 17, where the photonic crystal columns are configured to inhibit propagation of the light in predetermined directions to reduce divergence of the light.

20. The method of claim 17, further comprising:
placing an interposer between electrodes on the transparent P-type semiconductor layer and electrodes of an electrical circuit on a silicon semiconductor substrate.
